(19) United States
(12) Patent Application Publication
(10) Pub. No.: US 2020/0013645 A1
(43) Pub. Date: Jan. 9, 2020

(54) LED LAMP FOR HEATING AND WAFER HEATING DEVICE INCLUDING THE SAME

(71) Applicant: PHOENIX ELECTRIC CO., LTD, Himeji-shi (JP)

(72) Inventor: Tetsuya GOUDA, Himeji-shi (JP)

(21) Appl. No.: 16/449,745

(22) Filed: Jun. 24, 2019

(30) Foreign Application Priority Data
Jul. 9, 2018 (JP) 2018-130305

(51) Int. Cl. H01L 21/67; G01R 31/28

(52) U.S. Cl. CPC H01L 21/67115; H01L 21/67248; G01R 31/2862; G01R 31/2875; G01R 31/2879

(57) ABSTRACT

An LED lamp for heating includes a substrate and a plurality of LEDs. The LEDs are mounted on a surface of the substrate.

### CROSS REFERENCE OF RELATED APPLICATION

This application claims the priority of Japanese Patent Application No. 2018-130305 filed on Jul. 9, 2018, which are incorporated by reference herein.

### BACKGROUND OF THE INVENTION

### Field of the Invention

The present invention relates to an LED lamp for heating a wafer and a wafer heating device including the same.

### Background Art

A device for heating a wafer for manufacturing a semiconductor with an LED lamp has been proposed, for example, in Laid-open Patent Application Publication No. 2012-178576 (Dome Type) and 2005-536045 (Shell type).

In addition, in the manufacturing process of semiconductors, “burn-in” may be performed in which the completed semiconductor is further heated after being loaded with a voltage or an operating frequency equal to or higher than a maximum rating for the purpose of screening an initial defective product. And it has also been proposed to use an LED lamp for heating in the burn-in, for example, in Laid-open Patent Application Publication No. 2002-208620.

### SUMMARY OF THE INVENTION

However, since to conduct the burn-in for the completed semiconductors is very costly, in recent years, some manufacturers have abolished the burn-in process. Also, a “wafer level burn-in” has been proposed in which burn-in is performed first in a state where the semiconductor is still a wafer and not is completed instead of abolishing the burn-in process. In the case of a completed semiconductor, the burn-in is usually performed for several hours to several tens of hours, and in the case of the burn-in for a wafer, only several tens of seconds may be required in some cases, so that the semiconductor manufacturing cost can be greatly reduced.

However, when the burn-in for the wafer is to be conducted, it is necessary to raise a temperature of the wafer to a necessary temperature in a short time and uniformly. But conventional LED lamps for heating cannot uniformly heat the wafer in a short time. That results in a problem that the temperature variation becomes large.

The present invention has been made in view of the above-mentioned problems, and an object thereof is to provide an LED lamp for heating capable of raising a temperature of a wafer to a necessary temperature in a short time and uniformly, and a wafer heating device including the same.

According to an aspect of the present invention, an LED lamp for heating includes a substrate and a plurality of LEDs. The LEDs are mounted on a surface of the substrate.

According to another aspect of the present invention, a wafer heating device includes the LED lamp for heating and a heating furnace body.

According to the present invention, the LEDs can be arranged more densely than before by employing the LEDs of the COB (Chip On Board) type, which are LEDs mounted on the surfaces of the substrates, it is possible to provide an LED lamp for heating capable of raising the temperature of the wafer to a required temperature in a short time and uniformly, and a wafer heating device including the same.

### BRIEF DESCRIPTION OF THE DRAWINGS

FIG. 1 is a diagram showing an LED lamp for heating 100 according to an embodiment.

FIG. 2 shows a heating device 200 according to an embodiment.

FIG. 3 is a diagram showing examples of arrangement intervals between LEDs 120.

FIG. 4 is a diagram showing another exemplary arrangement of LEDs 120 interval.

FIG. 5 shows an exemplary arrangement of LEDs 120 on a single substrate 110.

FIG. 6 is a diagram showing an example of a state in which an LED lamp for heating 100 is formed by combining a plurality of substrates 110.

FIG. 7 is a diagram showing another embodiment in which LEDs 120 are arranged on a single substrate 110.

FIG. 8 is a diagram showing another example of a state in which an LED lamp for heating 100 is formed by combining a plurality of substrates 110.

FIG. 9 is a diagram showing a heating device 200 according to another embodiment.

### DETAILED DESCRIPTION OF EMBODIMENTS

(Structure of the LED Lamp for Heating 100)

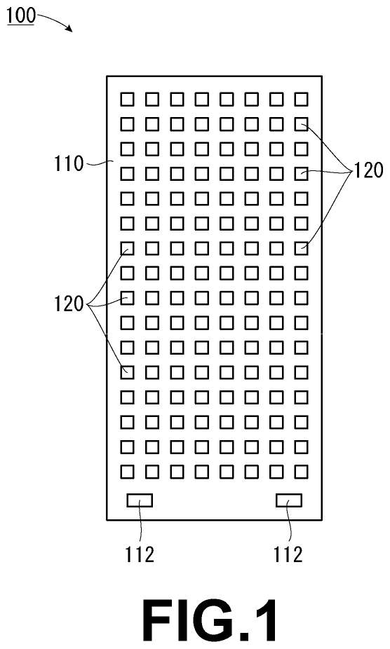

An LED lamp for heating 100 to which the present invention is applied will be described with reference to the drawings. FIG. 1 is a diagram showing an LED lamp for heating 100 according to the present embodiment.

The LED lamp for heating 100 according to the present embodiment is generally composed of a substrate 110 and a plurality of LEDs 120 mounted on the surface of the substrate 110. Here, “mounted” means that the LEDs 120 are mounted on the substrate 110 in a Chip On Board (COB) type.

A pair of electrodes 112 is formed on the surface of one end portion of the substrate 110, and the respective LEDs 120 mounted on the surface of the substrate 110 are connected in series between the electrodes 112 with circuit patterns (not shown). As a result, the currents flowing in the respective LEDs 120 become the same, and variations in the values of the currents flowing in the respective LEDs 120 are eliminated, so that variations in the amounts of light emitted from the respective LEDs 120 can also be minimized.

Further, it is preferable to use a plurality of the LED lamp for heating 100 in combination according to the size of the wafer W to be subjected to the heat treatment. This is because, by using a plurality of the LED lamp for heating 100, which are smaller to some extent (on which a small number of LEDs 120 are mounted), rather than one large LED lamp for heating 100 (on which a large number of LEDs 120 are mounted), it becomes easy to adjust the amount of heat applied to the wafer W. And it is possible to intentionally separate a region of the wafer W in which the amount of heat applied to is large and a region of the wafer W in which the amount of heat applied to is small as required.

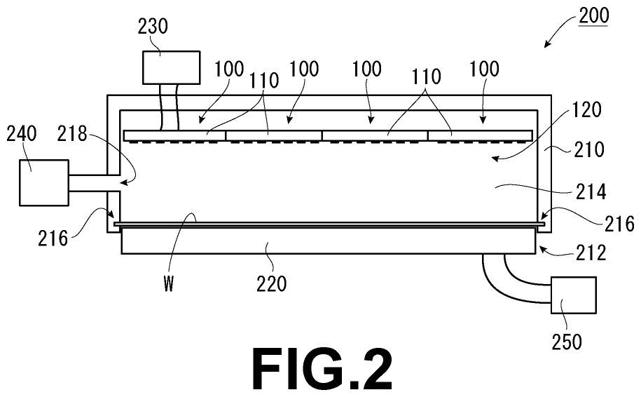

Next, the heating device 200 for conducting the “burning in” to the wafer W using the plurality of the LED lamps for heating 100 described above will be described. As shown in FIG. 2, the heating device 200 generally includes a plurality of LED lamps for heating 100, a heating furnace body 210, a wafer table 220, an LED lamp for heating control device 230, a pressure control device 240, and a wafer tester 250.

The heating furnace body 210 is a box-like body having an opening 212 at the lower end in the figure, and a plurality of LED lamps for heating 100 are disposed above an internal space 214 thereof. A wafer holding portion 216 is formed at the lower end portion of the heating furnace body 210 to hold the wafer W to be subjected to burn-in and to hermetically seal the internal space 214 while holding the wafer W. Further, a pressure regulating hole 218 for regulating the pressure in the airtight internal space 214 is formed in the heating furnace body 210, and the pressure regulating hole 218 is connected to the pressure control device 240. The combination of the heating furnace body 210 and the LED lamps for heating 100 is referred to as a “wafer heating device”.

The wafer table 220 is a device for placing a wafer W to be subjected to burn-in, and for testing the wafer W by supplying a predetermined voltage or current to a circuit formed on the mounted wafer W. The wafer table 220 is electrically connected to the wafer tester 250. And testing of the wafer W is controlled and performed by the wafer tester 250.

The LED lamp for heating control device 230 is a device that supplies power to each of the plurality of the LED lamps for heating 100 disposed in the heating furnace body 210, adjusts and controls a current value and the like for each of the LED lamps for heating 100, and supplies a uniform and optimal amount of heat to the wafer W.

The pressure control device 240 is a device for controlling the pressure of the internal space 214 of the heating furnace body 210. And the internal space 214 is controlled so as to have a pressure higher than the atmospheric pressure when the wafer W is burned in.

Preferred items of each element constituting the heating device 200 will be described below.

(Wavelength)

When mounting the LEDs 120 on the substrate 110 of the LED lamp for heating 100, it is common to use a silicone resin for sealing. But it has been confirmed that the silicone resin for sealing is deteriorated at an early stage by UV-light of 400 nm or less. However, since the absorption wavelength of a silicon wafer generally used is high in the vicinity of 300 nm and tends to decrease as the wavelength becomes longer from the vicinity of 400 nm, it is pointed out that a lifetime is extremely short when a silicone resin for sealing is used.

On the other hand, when the effect of the difference in the wavelength of light on the heating performance of the wafer W was examined, it was found that the temperature rise rate and the reaching limit temperature of the wafer W were substantially equal in the case of 385 nm and the case of 810 to 980 nm.

Therefore, it is preferable that the wavelength of the light emitted from the LEDs 120 in the LED lamp for heating 100 is 810 nm or more and 980 nm or less. As a result, the possibility of deterioration of the sealing silicone resin used in the LED lamps for heating 100 can be reduced. In other words, the sealing silicone resin can be used for the LED lamps for heating 100 without any problem.

(Structure of the LED 120)

In the LED 120, it is preferable to use a double junction chip having two light emitting layers. As a result, the amount of light emitted per unit area of the LED lamp for heating 100 can be increased.

(Spacing between Two or More LEDs 120)

The spacing at which a plurality of the LEDs 120 mounted on the substrate 110 is preferably less than 2 mm between the centers of the LEDs 120 when the sizes of each LED 120 are 1 mm squares, and more preferably less than 1.5 mm. In this manner, by mounting the respective LEDs 120 on the substrate 110 in the Chip On Board (COB) type, the LEDs 120 can be disposed at a high density, and the amount of light of the LED lamps for heating 100 can be increased. In addition, since the COB-type LEDs 120 are directly mounted on the substrate 110, the thermal resistivity at the time of heat transfer from the LEDs 120 to the substrate 110 becomes small, and the heat generated in the LEDs 120 can be efficiently dissipated to the substrate 110.

On the other hand, in the case of a conventional shell type or dome type LED lamp, it is difficult to arrange the center-to-center spacing of the LEDs to be less than 3 mm. In addition, when the size of each LED 120 itself is increased, the amount of light per unit area increases, but it becomes difficult for heat generated from each LED to escape.

(Arrangements of the Multiple LEDs 120)

It is conceivable that the mounting arrangement shape of each LED 120 on the substrate 110 is a lattice shape or a staggered lattice shape in which the distance between each LED 120 is constant.

In order to improve the uniformity of the temperature of the wafer W at the time of temperature stabilization after the temperature of the wafer W is raised, it is also conceivable that the mounting arrangement intervals of the respective LEDs 120 are made unequal.

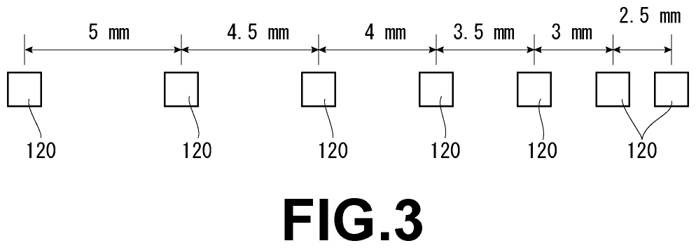

For example, as the distance from the central position of the LED lamp for heating 100 to the outer position, the spacing between the LEDs 120 may be reduced by a certain length (distance) (see FIG. 3), or the spacing between the LEDs 120 may be reduced by a certain percentage. Note that the interval dimension values in the figures are examples.

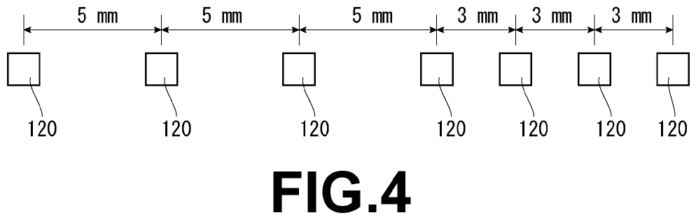

Also, as shown in FIG. 4, the LEDs 120 may be placed at equal intervals from the central position to the outer position of the LED lamp for heating 100 to a predetermined value, and the LEDs 120 may be further placed at equal intervals with shorter than a predetermined number of outer positions. Note that the interval dimension values in the figures are examples.

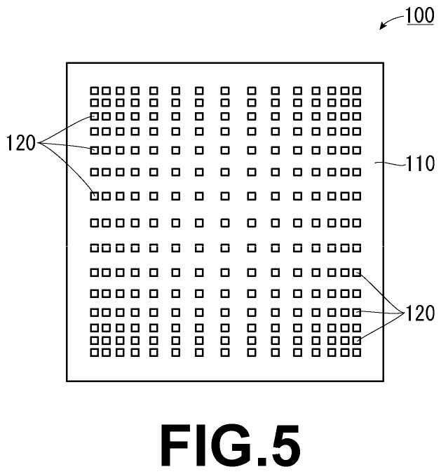

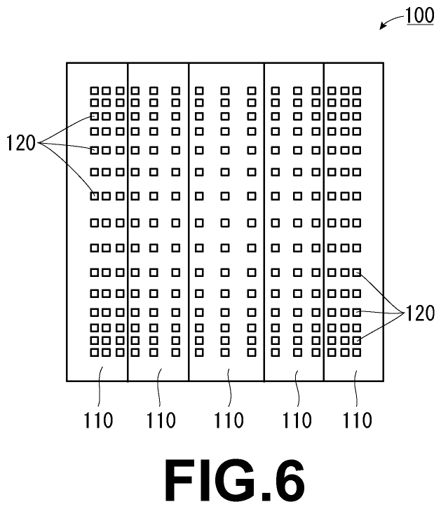

Further, as shown in FIG. 5, the LEDs 120 may be arranged on one substrate 110 at unequal intervals as described above, or by combining a plurality of substrates 110 as shown in FIG. 6, the LED lamp for heating 100 in which the LEDs 120 are arranged at unequal intervals may be formed.

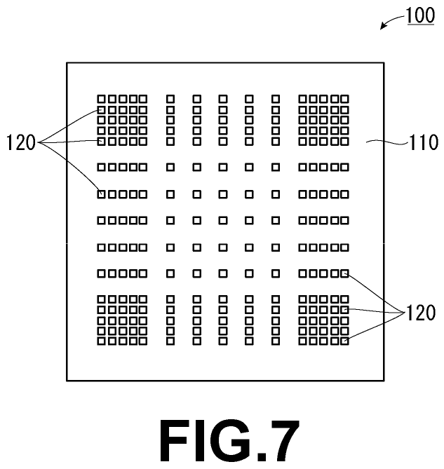

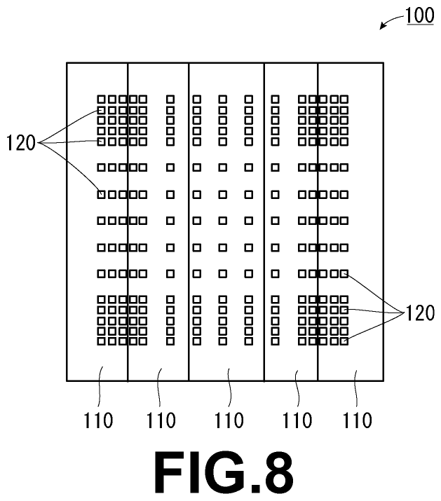

Of course, the same applies to the case where the LEDs 120 are arranged so as to change the length at equal intervals in the middle, and as shown in FIG. 7, the LEDs 120 may be arranged on one substrate 110 at the above-mentioned intervals, or as shown in FIG. 8, the LED lamp for heating 100 in which the LEDs 120 are arranged at predetermined intervals may be formed by combining a plurality of the substrates 110.

(Relationship between Area of Light-Emitting Surface of the LED Lamp for Heating 100 and Area of the Wafer W)

Preferably, the area of the light emitting surface in the LED lamp for heating 100 is designed to be greater than the area of the wafer W. And the light from the LEDs 120 located at the periphery of the emitting surface is not exposed to the wafer W so that these LEDs 120 are not used to heat the wafer W.

The LEDs 120 located near the center of the light emitting surface receive heat from the surrounding LEDs 120 as well as heat from themselves and become high temperature. On the other hand, the temperature of the LEDs 120 themselves is lower than the temperature of the LEDs 120 located near the center because the LEDs 120 located at the periphery of the light-emitting surface are unlikely to be at a high temperature. Therefore, the amount and wavelength of the light from the LEDs 120 located at the peripheral portion are different from the amount and wavelength of the light from the LEDs 120 located near the center. And if the light from the LEDs 120 located at the peripheral portion is used to heat the wafer W, the uniformity of heating may be lowered.

The diameter of the light emitting surface of the LED lamp for heating 100 is preferably in a range in which the following two equations are satisfied with respect to the diameter of the wafer W.

A=C×R×B (1)

0.063<R≤0.0845 (2)

A: Diameter [mm] of the light emitting surface

B: Distance [mm] between the LED lamp for heating 100 and the wafer W

C: Diameter [mm] of the wafer W

R: A variable

The reason why the above ranges are preferable is that the light emitted from the peripheral portion of the light emitting surface of the LED lamp for heating 100 is weaker than the light emitted from the central portion of the light emitting surface due to the relationship between the densities of the arranged LEDs 120, and therefore the relationship between the diameter of the wafer W and the diameter of the light emitting surface greatly influences the uniformity of the temperature of the wafer W when the temperature of the wafer W to be heated rises and when the temperature stabilizes. With the above range, for example, when the distance between the LED lamp for heating 100 and the wafer W is 10 mm, the temperature uniformity of the wafer W is less than 10% of the temperature difference between the point where the temperature is highest and the point where the temperature is lowest in the wafer W. Note that the above ratio (%) is a value calculated by ([a value of temperature at the highest temperature point on the wafer W]-[a value of temperature at the lowest temperature point on the wafer W])/[a value of temperature at the highest temperature point on the wafer W]×100.

Further, it is more preferable that the diameter of the light emitting surface of the LED lamp for heating 100 is in a range in which the following two equations are satisfied with respect to the diameter of the wafer W.

A=C×R×B (1)

0.063<R0.0769 (3)

A: Diameter [mm] of the light emitting surface

B: Distance [mm] between the LED lamp for heating 100 and the wafer W

C: Diameter [mm] of the wafer W

R: A variable

With the above range, for example, when the distance between the LED lamp for heating 100 and the wafer W is 10 mm, the temperature uniformity of the wafer W is such that the temperature difference between the point where the temperature is highest and the point where the temperature is lowest in the wafer W is less than 5%.

(Shape of the Substrate 110)

As for the shape of the substrate 110, it is preferable to arrange the rectangular or square substrates 110 so as to be adjacent to each other, and to set the area of the entire LED lamp for heating 100 to be larger than the area of the wafer W, as described above.

(Distance between the LED Lamp for Heating 100 and the Wafer W)

The distance between the LED lamp for heating 100 and the wafer W may be 1 mm or more, but if the distance is too short, it is disadvantageous in terms of the uniformity of heating of the wafer W, and therefore the distance should be at least 3 mm or more, preferably 5 mm or more, and more preferably 10 mm or more.

The uniformity of the heating of the wafer W should be such that the temperature difference between the point of the wafer W having the highest temperature and the point of the wafer W having the lowest temperature is 10% or less, preferably 5% or less, and more preferably 3% or less. Note that the above ratio (%) is a value calculated by ([a value of temperature at the highest temperature point on the wafer W]-[a value of temperature at the lowest temperature point on the wafer W]/[a value of temperature at the highest temperature point on the wafer W]×100.

(Control of Current Flow to the LEDs 120)

If the LED lamp for heating control device 230 increases the value of the current supplied to the respective LEDs 120, the amount of light emitted from the LEDs 120 increases, and the time required for heating the wafer W to a predetermined temperature can be shortened.

For example, in order to keep the temperature constant after the temperature of the wafer W is quickly raised to a predetermined temperature, a large current is caused to flow through the respective LEDs 120 during the temperature rise. And thereafter, if the current value is reduced when the temperature reaches the predetermined temperature, the temperature of the wafer W may overshoot the desired temperature. Therefore, by reducing the current values to be flowed to the respective LEDs 120 when the wafer W reaches the slightly lower temperature prior to reaching the predetermined temperature, it is possible to prevent the temperature from overshooting.

More specifically, to avoid the overshoot, the current value to be flowed to the respective LEDs 120 and reducing the current value how many seconds after that current value starts to be supplied or the like are measured in advance. Actually, the temperature of the wafer W can be prevented from overshooting by reducing the current value when a predetermined time elapsed after the start of energization of the respective LEDs 120. The predetermined time is decided based on the current value.

The method of avoiding the overshoot of the temperature of the wafer W is not limited to the above-mentioned method. For example, the temperature of the wafer W may be measured by thermography or the like, and the current value to the respective LEDs 120 may be reduced prior to the temperature reaching a desired value.

Further, when there is a variation in amount of the light between each LED 120, for example, when the LED lamp for heating 100 is configured by a plurality of the substrates 110, it is preferable to improve the uniformity of the heating of the wafer W by adjusting the current value to be supplied to the LEDs 120 for each substrate 110. In addition, the LEDs 120 on one substrate 110 may be divided into a plurality of groups and different circuits may be set for each group to adjust the current values for each group.

(Against Variations in the Amount of Light Inherent to the LED Lamp for Heating 100)

In the case where a plurality of the LED lamps for heating 100 is used in the heating device 200, even if a current of the same value is supplied to each of the LED lamps for heating 100, variation in the amount of light emitted from each of the LED lamps for heating 100 may be observed, and due to this variation, uniformity of heating of the wafer W by the heating device 200 may be lowered.

In order to against such a variation, it is considered that data of the current value in each of the LED lamps for heating 100 and the amount of light corresponding to the current value are acquired in advance. And the current value to be flowed to each LED 120 is corrected so that the light emission amount to the wafer W becomes uniform in the heating device 200 as a whole.

(Cooling of the LEDs 120)

If not only the wafer W but also the LEDs 120 themselves, which is being supplied with current and is emitting light, rises in temperature and the temperature of the LEDs 120 themselves rises excessively, problems may occur as the LED lamps for heating 100. The problems are such as a change in the wavelength of light emitting light or a decrease in the amount of emitted light. Therefore, it is preferable to dispose a sheet material or the like having a high heat radiation property on the back surface (the surface opposed to the surface on which the LEDs 120 are mounted) of the substrate 110. And the LEDs 120 is cooled by contacting the sheet material or the like to a water-cooled heat sink (not shown). An air cooling may be used when a temperature rise is moderate in each LED 120.

(Material of the Substrates 110)

As described above, in order to prevent the temperature of the LEDs 120 themselves from being excessively high, it is preferable to use a substrate based on aluminum, a substrate based on copper, or an alumina substrate or an aluminum nitride substrate having low thermal resistance. Further, as the size of the substrate 110 increases, the substrate 110 warps due to a difference between the thermal expansion coefficient of a base metal for the substrate such as aluminum or copper and the thermal expansion coefficient of a resin resist for fixing the LEDs 120. Therefore, when the size of the substrate 110 is large, it is preferable to use a ceramic-based substrate such as an alumina substrate or an aluminum nitride substrate which does not cause such a problem.

(Addition of Lenses 260)

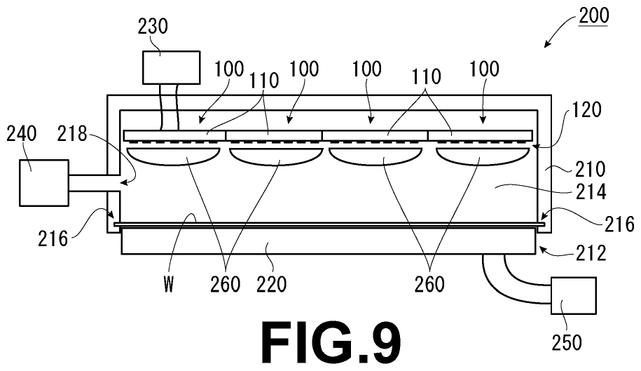

As shown in FIG. 9, lenses 260 for narrowing the directivity angle of light may be provided on the surfaces of the LED lamps for heating 100 facing the wafer W. By narrowing the directivity angle of the light from the LEDs 120 by the lenses 260, the light that deviates from the wafer W and does not contribute to the heating of the wafer W can also be used to heat the wafer W, so that an efficient LED lamps for heating 100 can be obtained. The number of the lenses 260 may be one lens 260 for one LED lamps for heating 100 (example of FIG. 9) or one lens may be provided for one LED 120.

(Gas Filled in the Internal Space 214 of the Heating Furnace Body 210)

It is preferable to use air, nitrogen, or an inert gas as the gas to be filled in the internal space 214 of the heating furnace body 210.

(Heating Capacity of the Heating Device 200)

As the heating capability of the heating device 200, it is preferable that the wafer W can be heated to 200° C. or more and 500° C. or less. And it is preferable that the temperature of the wafer W itself can be heated to the above-mentioned temperature in a period of 2 seconds or more and 10 seconds or less, preferably 2 seconds or more and 5 seconds or less, after the current starts to be supplied to the respective LEDs 120.

(Materials to Bond the LEDs 120 to the Substrate 110)

A resin-containing silver paste is generally used as a material for bonding the LEDs 120 to the substrate 110, but a Silver Nano paste without a resin is preferably used instead of the resin-containing silver paste. The metal bonding of the LEDs 120 to the substrate 110 using the Silver Nano paste is advantageous for cooling the LEDs 120 because the efficiency of heat transfer from the LEDs 120 to the substrate 110 (thermal conductivity) is about 10 times higher than that of conventional resin.

Although the invention has been described in its preferred form with a certain degree of particularity, it is understood that the present disclosure of the preferred form has been changed in the details of construction and the combination and arrangement of parts may be resorted to without departing from the spirit and scope of the invention as hereinafter claimed.

The disclosure of Japanese Patent Application No. 2018-130305 filed on Jul. 9, 2018 including specification, drawing and claims is incorporated herein by reference in its entirety.

What is claimed is:

1. An LED lamp for heating comprising:
a substrate; and
a plurality of LEDs mounted on a surface of the substrate.

2. A wafer heating device comprising:
the LED lamp for heating according to claim 1; and
a heating furnace body.
